(19) United States
(12) Patent Application Publication
(10) Pub. No.: US 2025/0238712 A1
(43) Pub. Date: Jul. 24, 2025

(54) Multi Agent Deep Reinforcement Learning System for Coverage Closure

(71) Applicant: Microsoft Technology Licensing, LLC, Redmond, WA (US)

(72) Inventors: Harikrishnan KUMARAPILLAI CHANDRIKAKUTTY, Santa Clara, CA (US); FNU SHASHANK, San Jose, CA (US); Sirish Kumar MUNIPALLI, Austin, TX (US); Aung Thu HTET, North Billerica, MA (US)

(21) Appl. No.: 18/421,260

(22) Filed: Jan. 24, 2024

(51) Int. Cl. G06N 20/00; G06F 30/33

(52) U.S. Cl. CPC G06N 20/00; G06F 30/33

(57) ABSTRACT

In one set of embodiments, a reinforcement learning (RL) agent in a plurality of RL agents can receive a current state of a testbench environment for an integrated circuit (IC) design, determine, via an RL model, policy, or function, an action to be applied to the testbench environment based on the current state, and transmit the action to the testbench environment. The RL agent can further receive, from the testbench environment, a reward value and a new state of the testbench environment and train the RL model, policy, or function based on the reward value, the current state, and the action, where the training causes the RL model, policy, or function to learn mappings between states of the testbench environment and actions to be applied to the testbench environment that maximize the reward value over time.

### BACKGROUND

Coverage closure is an iterative process performed during the design verification phase of an integrated circuit (IC) development project for ensuring that the IC design being verified (known as a Design Under Test or DUT) is thoroughly tested, thereby reducing the likelihood of bugs or errors in the final IC product. Coverage closure generally involves (1) defining a set of coverage goals for the DUT, where each coverage goal is a quantitative objective that verification engineers aim to achieve with respect to the scope of their DUT testing (e.g., 100% test coverage of the DUT source code, 100% test coverage of the functional behaviors of the DUT, etc.); (2) creating and executing test cases against the DUT (or in other words, providing input stimuli to the DUT that are intended to exercise certain areas of the DUT under various conditions and scenarios); (3) collecting information regarding how the DUT responds to the stimuli provided via the test cases; (4) analyzing the collected information to determine whether the coverage goals are met; and (5) if one or more coverage goals are not met (which means there are areas of the DUT that remain inadequately tested), repeating steps (2)-(4). Once the coverage goals are met, the DUT is considered successfully verified and can proceed to the next phases of development (e.g., synthesis and manufacturing).

One issue with the coverage closure process is that it is currently a time-consuming and largely manual endeavor. For example, in the scenario where the coverage analysis at step (4) indicates that a coverage goal is not met, a human verification engineer must manually interpret the test case results, identify coverage gaps, and modify/constrain the test cases (or create entirely new test cases) in an attempt to address the identified gaps. This will often need to be repeated many times due to the difficulties in comprehensively testing all aspects of a complex IC design.

### BRIEF DESCRIPTION OF THE DRAWINGS

FIG. 1 depicts an example testbench environment according to certain embodiments.

FIG. 2 depicts a multi-agent reinforcement learning system according to certain embodiments.

FIG. 3 depicts a flowchart that may be executed by the system of FIG. 2 for performing online learning-based coverage closure according to certain embodiments.

FIG. 4 depicts a flowchart that may be executed by the system of FIG. 2 for performing offline learning according to certain embodiments.

FIG. 5 depicts an example computer system according to certain embodiments.

### DETAILED DESCRIPTION

In the following description, for purposes of explanation, numerous examples and details are set forth in order to provide an understanding of various embodiments. It will be evident, however, to one skilled in the art that certain embodiments can be practiced without some of these details or can be practiced with modifications or equivalents thereof.

Embodiments of the present disclosure are directed to a multi-agent reinforcement learning system, referred to as MARL-CC, for implementing coverage closure in the context of IC design verification. Reinforcement learning is a machine learning technique that involves training an agent to take actions in an environment in order to maximize some reward. Multi-agent reinforcement learning involves training multiple independent agents rather than a single agent.

As detailed below, the MARL-CC system can automatically learn how to test a DUT in order to target uncovered areas of its design and thereby accelerate the coverage closure process. Accordingly, the system can significantly reduce the manpower and time needed to bring a new IC design to market.

### 1. Conventional Coverage Closure

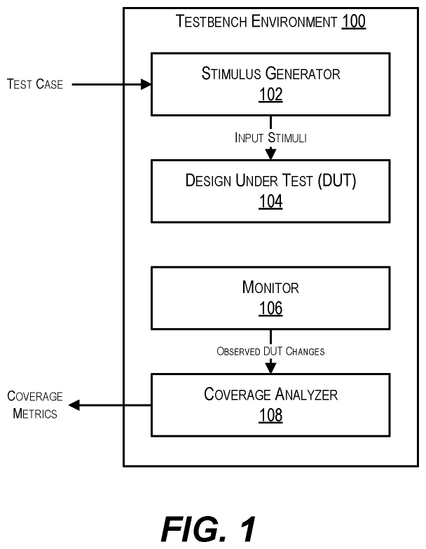

To provide context for the MARL-CC system of the present disclosure, FIG. 1 depicts an example testbench environment 100 that is used by a team of human verification engineers (i.e., verification team) for verifying an IC design using conventional coverage closure techniques. The IC design may be, e.g., a design for a microprocessor, a microcontroller, a digital signal processor (DSP), a memory module, or any other integrated circuit known in the art. Testbench environment 100 is typically implemented in software that runs on one or more computer systems. Examples of programming languages that may be used to implement testbench environment 100 include SystemVerilog and Verilog.

As shown, testbench environment 100 includes a stimulus generator 102, the IC design being verified (DUT 104), a monitor component 106, and a coverage analyzer 108. DUT 104 typically takes the form of source code that is written in a hardware description language (HDL) such as Verilog, VHDL, or the like. This source code specifies the structure and behavior of the logic elements that compose DUT 104, as well as the DUT's interfaces. Each such interface comprises a related group of connection points (i.e., pins) on which DUT 104 can receive signals from external entities for processing. Examples of common interfaces include the AXI (Advanced eXtensible Interface) and APB (Advanced Peripheral Bus) interfaces.

Generally speaking, the conventional coverage closure process begins by establishing, by the verification team, a set of coverage goals that should be met in order for DUT 104 to be considered successfully verified. These coverage goals are quantitative testing objectives that are specified in terms of coverage metrics such as code coverage, functional coverage, and assertion coverage. For example, one coverage goal may be to achieve 100% code coverage, which means that all parts of the source code of DUT 104 (e.g., executable statements, branches, etc.) have been tested and validated. Another coverage goal may be to achieve 100% functional coverage, which means that all functional attributes and behaviors of DUT 104 (as set forth in the DUT's functional design specification) have been tested and validated.

The verification team then sets up and executes a suite of test cases (i.e., test suite) against DUT 104 using testbench environment 100 for testing various areas of the DUT's design. The execution of each test case in the test suite involves (1) providing the test case as input to stimulus generator 102, where the test case comprises input stimuli (e.g., data and/or control signals) for the interfaces of DUT 104; (2) generating, via stimulus generator 102, the input stimuli indicated by the test case and driving the interfaces of DUT 104 using the generated stimuli, thereby causing DUT 104 to undergo a state transition; (3) observing, via monitor 106, changes in DUT 104 responsive to the input stimuli (e.g., changes to internal registers, values output by DUT 104, etc.), validating that the changes are correct/expected, and providing information regarding the observed changes to coverage analyzer 108; and (4) computing, via coverage analyzer 108, coverage metrics for DUT 104 in view of the information received from monitor 106.

In many scenarios the test cases of the test suite will be randomly generated, subject to certain constraints on the random generation process as defined by the verification team. This technique is known as constraint random verification or CRV. Further, the test suite will typically be scheduled for execution at night (due to being time consuming and computationally expensive) and thus is sometimes referred to as a “nightly regression.”

Once the test suite is executed, the verification team reviews the coverage metrics computed and output by coverage analyzer 108 to determine whether the coverage goals for DUT 104 are met. If one or more coverage goals are not met, the verification team interprets the test cases and resulting coverage metrics to identify gaps in coverage (i.e., areas of DUT 104 that have not yet been covered/tested). The verification team then sets up a modified test suite with modifications/constraints to the prior test cases (and/or with brand new, hand-crafted test cases) that are intended to target the coverage gaps.

Finally, the steps of test suite execution, coverage metric review, and test suite modification are repeated until all coverage goals are met.

### 2. Solution Overview

While the conventional coverage closure process described above is functional, it is also time-consuming and burdensome due to the need for human verification engineers to manually review the results of each test suite execution, identify coverage gaps, and modify existing test cases and/or create new test cases in an attempt to fill those gaps. In many cases (and particularly for complex IC designs), the engineers will need to repeat these steps many times in order to build a test suite that covers all aspects of the DUT adequately. This in turn can negatively impact the time to market for the IC design.

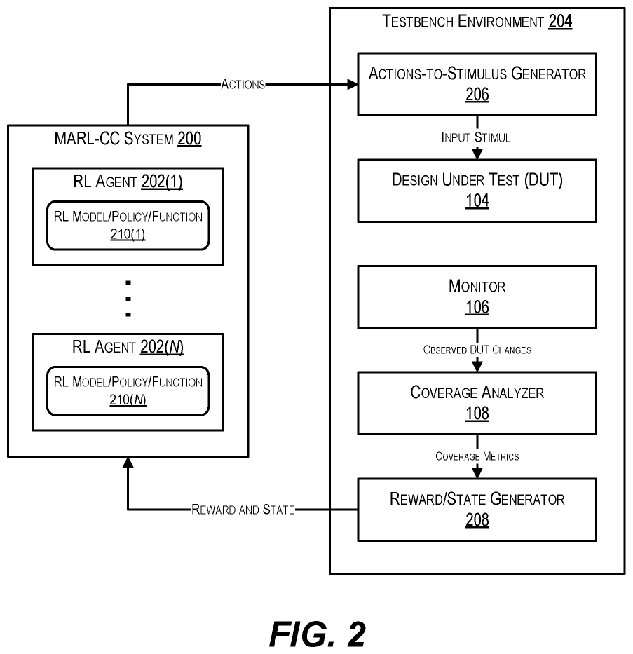

To address the foregoing and other related issues, FIG. 2 depicts a novel multi-agent reinforcement learning system for implementing coverage closure (i.e., MARL-CC system 200) according to certain embodiments. As shown, MARL-CC system 200 includes a set of reinforcement learning (RL) agents 202(1)-(N) that are communicatively coupled with an enhanced version 204 of testbench environment 100 of FIG. 1. Enhanced testbench environment 204 includes, beyond existing components 104-108, a new actions-to-stimulus generator 206 (in place of stimulus generator 102) and a new reward/state generator 208.

Like the testbench environment, RL agents 202(1)-(N) can be implemented in software that runs on one or more computer systems. In embodiments where RL agents 202(1)-(N) and testbench environment 204 are implemented using different programming languages (e.g., Python and SystemVerilog respectively), the RL agents can communicate with the testbench environment via appropriate language adapters.

At a high level, MARL-CC system 200 can interact with testbench environment 204 in order to carry out the coverage closure process for DUT 104 as follows:
1. Each RL agent 202(i) for i=1 . . . N determines, using an internal RL model, policy, or function 210(i), an action to be taken on testbench environment 204 (and in particular, on DUT 104) based on a current state of environment 204 and transmits the action to actions-to-stimulus generator 206. In one set of embodiments, each RL agent 202(i) can be associated with a particular interface i of DUT 104 and the action determined by RL agent 202(i) can comprise a set of values corresponding to input stimuli to be provided to DUT 104 on interface i. For example, the action determined by RL agent 202(1) can comprise values corresponding to input stimuli for a first interface of DUT 104, the action determined by RL agent 202(2) can comprise values corresponding to input stimuli for a second interface of DUT 104, and so on.
2. Actions-to-stimulus generator 206 receives the actions transmitted by RL agents 202(1)-(N), converts the actions into their corresponding input stimuli, and uses the input stimuli to drive the interfaces of DUT 104 (or in other words, inject the input stimuli on the interfaces using appropriate clock timing). As noted above, the input stimuli generated from the action determined by a particular RL agent 202(i) can be used to drive a particular interface i.
3. Monitor 106 monitors for and observes changes in DUT 104 that result from the input stimuli injected by actions-to-stimulus generator 206, validates that the changes are correct/expected, and provides information regarding the observed changes to coverage analyzer 108. In response, coverage analyzer 108 computes coverage metrics for DUT 104 based on the DUT change information and provides the computed metrics to reward/state generator 208.
4. Assuming the coverage goals of DUT 104 are not met at this point, reward/state generator 208 compares the coverage metrics received from coverage analyzer 108 against a set of coverage metrics associated with a previous state of testbench environment 204 and based on this comparison, generates a reward value indicating the desirability of the actions output by the RL agents for the current environment state. For example, if the actions resulted in an increase (i.e., improvement) in coverage with respect to one or more coverage metrics, reward/state generator 208 may generate a positive reward value. Conversely, if the actions resulted in no change in coverage (or a regression in coverage) for one or more coverage metrics, reward/state generator 208 may generate a zero or negative reward value. Reward/state generator 208 also generates a new (now current) state of testbench environment 204 with respect to each RL agent and transmits the reward and new state to the agents.
5. Upon receiving the reward and new state information transmitted by reward/state generator 208, each RL agent 202(i) uses the reward value as feedback to train (or more precisely, update the training of) its internal RL model/policy/function 210(i). This training step causes the RL model/policy/function to move closer towards learning optimal environment state-to-action mappings that maximize the total cumulative reward received from testbench environment 204 over time (and thus lead to coverage closure).
6. Finally, each RL agent 202(i) determines, using its updated RL model/policy/function 210(i), a new action based on the new environment state and transmits the new action to actions-to-stimulus generator 206. Steps (2)-(6) are thereafter repeated until all coverage goals are met.

With the general architecture and workflow described above, a number of advantages are realized. First, because MARL-CC system 200 leverages RL to automatically learn how to create actions for testbench environment 204 (which correspond to test cases for DUT 104) that target previously uncovered areas of the DUT without human intervention, the system can significantly streamline and accelerate the coverage closure process. It should be noted that the foregoing coverage closure workflow is considered an “online learning” workflow due to the way in which it continuously trains RL agents 202(1)-(N) while concurrently interacting with testbench environment 204.

Second, because MARL-CC system 200 is not tied to a particular RL algorithm or approach, RL agents 202(1)-(N) can flexibly support various different types of RL algorithms such as deep RL, Q-learning, and policy gradient methods.

Third, because MARL-CC system 200 is composed of multiple RL agents and each RL agent is responsible for generating actions for a disjoint subset of input signals (e.g., a particular interface) of DUT 104, the system can achieve faster learning and improved scalability for handling complex IC designs in comparison to single-agent systems.

The remaining sections of this disclosure provide additional details regarding the online learning-based coverage closure workflow above, as well as a description of a separate offline learning workflow that can be used to pre-train RL agents 202(1)-(N) before they are deployed for performing coverage closure on a DUT. It should be appreciated that FIG. 2 is illustrative and not intended to limit embodiments of the present disclosure. For example, although this figure depicts a particular arrangement of components within MARL-CC system 200, other arrangements are possible (e.g., the functionality attributed to a particular component may be split into multiple components, components may be combined, etc.). One of ordinary skill in the art will recognize other variations, modifications, and alternatives.

### 3. Online Learning

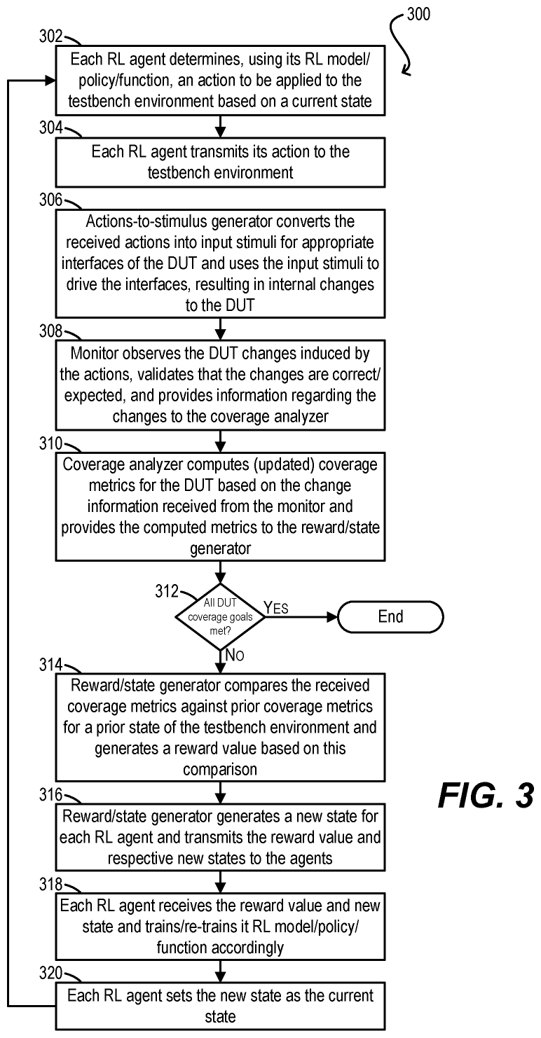

FIG. 3 depicts a flowchart 300 of the online learning-based coverage closure workflow described in section (2) above according to certain embodiments. Flowchart 300 assumes that each RL agent 202(i) of MARL-CC system 200 has received a state value s(i) from reward/state generator 208 that indicates the current state or configuration of testbench environment 204 with respect to RL agent 202(i). In one of set of embodiments s(i) may include a concatenated sequence of the prior M actions output by RL agent 202(i) and transmitted to environment 204, where M is some value configured by the system administrators. In other embodiments, s(i) may include other information relevant to the current state of testbench environment 204, either in addition to or in lieu of this concatenated action sequence. For example, s(i) may include some subset of prior actions output by the other RL agents.

Starting with block 302 of flowchart 300, each RL agent 202(i) can provide state s(i) as input to its RL model/policy/function 210(i), resulting in the determination of an action a(i) to be taken on (or in other words, applied to) testbench environment 204 in view of s(i). As noted previously, action a(i) comprises a set of values that correspond to input stimuli to be provided to DUT 104 in order to test the DUT. In certain embodiments, these values may map to the input signals for a particular interface i of DUT 104 that is associated with/mapped to the RL agent. At block 304, each RL agent 202(i) can transmit its action a(i) to testbench environment 204.

At block 306, actions-to-stimulus generator 206 of testbench environment 204 can receive the actions, convert them into their corresponding input stimuli, and use the input stimuli to drive the appropriate interfaces of DUT 104. This can induce one or more changes in DUT 104, such as modifications to internal registers or the output of values on one or more egress interfaces.

At block 308, monitor 106 (which is configured to monitor the internal state of DUT 104) can observe the DUT changes induced by the input stimuli at block 306 and, for each such change, can validate that the change is correct (i.e., is an expected behavior given the input stimuli). Monitor 106 can then provide information regarding the DUT changes to coverage analyzer 108.

In response, coverage analyzer 108 can compute coverage metrics for DUT 104 based on the change information received from monitor 106 and provide the computed coverage metrics to reward/state generator 208 (block 310). For example, coverage analyzer 108 may determine that the DUT changes result in 23% code coverage and 35% functional coverage.

At block 312, reward/state generator 208 can check whether the coverage metrics received from coverage analyzer 108 indicate that the coverage goals for DUT 104 are met. If the answer is yes, the coverage closure process can be considered complete and the flowchart can end.

However, if the answer at block 312 is no, reward/state generator 208 can compare the received coverage metrics against prior coverage metrics computed with respect to a prior state of test bench environment 204 and generate a reward value r based on this comparison (block 314). For example, reward/state generator 208 can generate a positive reward value if the current set of actions from RL agents 202(1)-(N) resulted in an improvement in coverage, and can generate a zero or negative reward value if the current set of actions from RL agents 202(1)-(N) resulted in no improvement or a regression in coverage.

Further, at block 316, reward/state generator 208 can generate a new state s(i)′ for each RL agent 202(i) and can transmit reward value r and the respective new states to the RL agents. Like original state s(i), new state s(i)′ may be computed as the prior M actions output by RL agent 202(i).

At block 318, each RL agent 202(i) can receive reward value r and new state s(i)′ and can train its internal RL model/policy/function 210(i) based on r, a(i), and original state s(i). This training, which can be implemented using known RL training techniques, is designed to teach the RL model/policy/function to choose actions based on environment states that maximize the cumulative reward received from testbench environment 204 over time.

Finally, RL agent 202(i) can set new state s(i)′ as the current state s(i) (block 320) and flowchart 300 can return to block 302. The foregoing process can subsequently repeat until all coverage goals of DUT 104 are met.

### 4. Offline Learning

In addition to the online learning-based coverage closure workflow above, in certain embodiments MARL-CC system 200 can implement an offline learning workflow. With this offline learning workflow, MARL-CC system 200 can train RL agents 202(1)-(N) using a fixed dataset, referred to as a replay buffer, that is derived from one or more test suites that were previously executed against testbench environment 204 via the conventional coverage closure process described in section (1), such as one or more prior nightly regressions. This can be useful for “pre-training” the RL agents to a threshold level prior to deploying them to carry out the online-based coverage closure workflow of FIG. 3, which in turn can make that online process more efficient and/or effective.

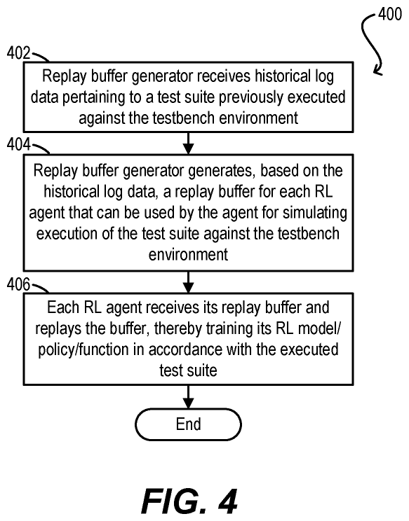

FIG. 4 depicts a flowchart 400 that may be executed by MARL-CC system 200 for implementing offline learning according to certain embodiments. Flowchart 400 assumes that MARL-CC system 200 includes a replay buffer generator component that is communicatively coupled with RL agents 202(1)-(N). This replay buffer generator may run on the same computer system(s) as RL agents 202(1)-(N) or on a separate set of computer systems.

Starting with block 402 of flowchart 400, the replay buffer generator can receive historical log data pertaining to a test suite that was previously executed against testbench environment 204/DUT 104. For example, the historical log data can pertain to a previously-executed nightly regression where the nightly regression comprises a set of test cases setup/defined by the verification team and where the historical log data includes, for each test case, the input stimuli provided to DUT 104 and the resulting coverage metrics computed by coverage analyzer 108.

At block 404, the replay buffer generator can generate, based on the received log data, a replay buffer B(i) for each RL agent 202(i) that can be used by the RL agent to simulate the execution of the test suite against testbench environment 204. For example, in one set embodiments each replay buffer B(i) can comprise a set of tuples and each tuple (which corresponds to a test case in the test suite) and can include: (1) an initial environment state s for the test case, (2) an action a that should be determined and output by RL agent 202(i) (per the input stimuli associated with the test case in the log data), (3) a reward value r that will be received by the RL agent in response to action a, and (4) a next environment state s′.

Finally, at block 406, each RL agent 202(i) can receive its corresponding replay buffer B(i) and can “replay” the buffer, thereby training its RL model/policy/function 210(i) in accordance with the executed test suite. Note that this replay process does not require any interaction with testbench environment 204 as in the online workflow of FIG. 3; instead, each RL agent 202(i) simulates such interactions based on the tuples in replay buffer B(i). For example, for each tuple (s, a, r, s′) in B(i), RL agent 202(i) can output action a, take as input reward r and next state s′, and update the training of its RL model/policy/function 210(i) in accordance with s, a, r, and s′.

### 5. Example Computer System

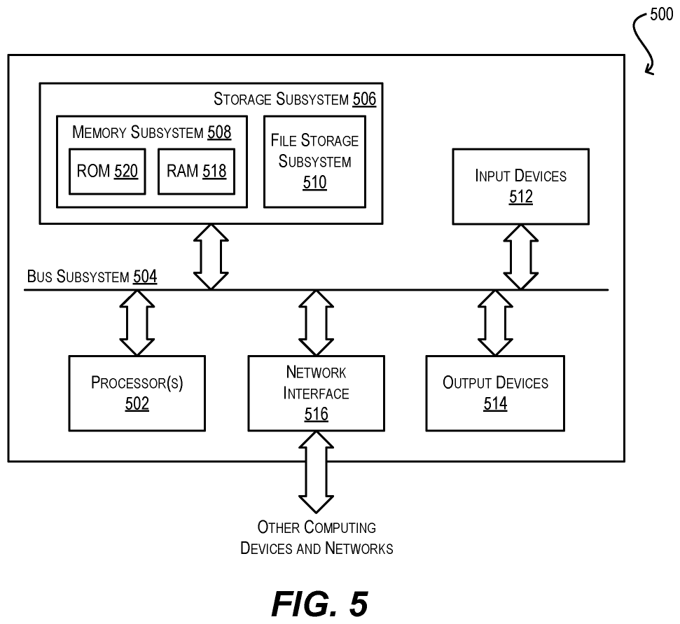

FIG. 5 is a simplified block diagram of an example computer system 500 according to certain embodiments. Computer system 500 (and/or equivalent systems/devices) may be used to run any of the software components described in the foregoing disclosure, including MARL-CC system 200 and/or testbench environment 204 of FIG. 2. As shown in FIG. 5, computer system 500 includes one or more processors 502 that communicate with a number of peripheral devices via a bus subsystem 504. These peripheral devices include a storage subsystem 506 (comprising a memory subsystem 508 and a file storage subsystem 510), user interface input devices 512, user interface output devices 514, and a network interface subsystem 516.

Bus subsystem 504 can provide a mechanism for letting the various components and subsystems of computer system 500 communicate with each other as intended. Although bus subsystem 504 is shown schematically as a single bus, alternative embodiments of the bus subsystem can utilize multiple buses.

Network interface subsystem 516 can serve as an interface for communicating data between computer system 500 and other computer systems or networks. Embodiments of network interface subsystem 516 can include, e.g., an Ethernet module, a Wi-Fi and/or cellular connectivity module, and/or the like.

User interface input devices 512 can include a keyboard, pointing devices (e.g., mouse, trackball, touchpad, etc.), a touch-screen incorporated into a display, audio input devices (e.g., voice recognition systems, microphones, etc.), motion-based controllers, and other types of input devices. In general, use of the term “input device” is intended to include all possible types of devices and mechanisms for inputting information into computer system 500.

User interface output devices 514 can include a display subsystem and non-visual output devices such as audio output devices, etc. The display subsystem can be, e.g., a transparent or non-transparent display screen such as a liquid crystal display (LCD) or organic light-emitting diode (OLED) display that is capable of presenting 2D and/or 3D imagery. In general, use of the term “output device” is intended to include all possible types of devices and mechanisms for outputting information from computer system 500.

Storage subsystem 506 includes a memory subsystem 508 and a file/disk storage subsystem 510. Subsystems 508 and 510 represent non-transitory computer-readable storage media that can store program code and/or data that provide the functionality of embodiments of the present disclosure.

Memory subsystem 508 includes a number of memories including a main random access memory (RAM) 518 for storage of instructions and data during program execution and a read-only memory (ROM) 520 in which fixed instructions are stored. File storage subsystem 510 can provide persistent (i.e., non-volatile) storage for program and data files, and can include a magnetic or solid-state hard disk drive, an optical drive along with associated removable media (e.g., CD-ROM, DVD, Blu-Ray, etc.), a removable or non-removable flash memory-based drive, and/or other types of non-volatile storage media known in the art.

It should be appreciated that computer system 500 is illustrative and other configurations having more or fewer components than computer system 500 are possible.

The above description illustrates various embodiments of the present disclosure along with examples of how aspects of these embodiments may be implemented. The above examples and embodiments should not be deemed to be the only embodiments, and are presented to illustrate the flexibility and advantages of the present disclosure as defined by the following claims. For example, although certain embodiments have been described with respect to particular workflows and steps, it should be apparent to those skilled in the art that the scope of the present disclosure is not strictly limited to the described workflows and steps. Steps described as sequential may be executed in parallel, order of steps may be varied, and steps may be modified, combined, added, or omitted. As another example, although certain embodiments may have been described using a particular combination of hardware and software, it should be recognized that other combinations of hardware and software are possible, and that specific operations described as being implemented in hardware can also be implemented in software and vice versa.

The specification and drawings are, accordingly, to be regarded in an illustrative rather than restrictive sense. Other arrangements, embodiments, implementations, and equivalents will be evident to those skilled in the art and may be employed without departing from the spirit and scope of the present disclosure as set forth in the following claims.

What is claimed is:

1. A method performed by a reinforcement learning (RL) agent in a plurality of RL agents, the method comprising:
receiving a current state of a testbench environment for an integrated circuit (IC) design;
determining, via an RL model, policy, or function of the RL agent, an action to be applied to the testbench environment based on the current state;
transmitting the action to the testbench environment;
in response to transmitting the action, receiving from the testbench environment a reward value and a new state of the testbench environment; and
training the RL model, policy, or function based on the reward value, the current state, and the action, the training causing the RL model, policy, or function to learn mappings between states of the testbench environment and actions to be applied to the testbench environment that maximize the reward value over time.

2. The method of claim 1 wherein the action comprises a set of values that correspond to input stimuli to be provided as input to the IC design.

3. The method of claim 1 wherein the input stimuli pertain to a particular interface of the IC design that is associated with the RL agent, and wherein each RL agent in the plurality of RL agents is associated with a different interface of the IC design.

4. The method of claim 1 wherein the reward value indicates whether application of the action to the testbench environment resulted in an improvement in one or more coverage metrics for the IC design.

5. The method of claim 1 wherein the reward value is a positive value in a scenario where application of the action to the testbench environment resulted in an improvement in one or more coverage metrics for the IC design.

6. The method of claim 1 wherein the reward value is a zero or negative value in a scenario where application of the action to the testbench environment resulted in no improvement in one or more coverage metrics for the IC design.

7. The method of claim 1 further comprising:
setting the new state as the current state; and
repeating the determining and transmitting of the action, the receiving of the reward value and the new state, and the training of the RL model, policy, or function until all coverage goals for the IC design are met.

8. The method of claim 1 wherein the current state includes a concatenated sequence of one or more prior actions determined by the RL agent.

9. The method of claim 1 wherein the RL model, policy, or function of the RL agent was previously trained using a replay buffer, the replay buffer comprising information pertaining to a suite of test cases that was previously executed against the testbench environment.

10. A computer system implementing a reinforcement learning (RL) agent in a plurality of RL agents, the computer system comprising:
a processor; and
a computer-readable medium having stored thereon instructions, that when executed by the processor, causes the processor to:
receive a current state of a testbench environment for an integrated circuit (IC) design;
determine, via an RL model, policy, or function, an action to be applied to the testbench environment based on the current state;
transmit the action to the testbench environment;
in response to transmitting the action, receive from the testbench environment a reward value and a new state of the testbench environment; and
train the RL model, policy, or function based on the reward value, the current state, and the action, the training causing the RL model, policy, or function to learn mappings between states of the testbench environment and actions to be applied to the testbench environment that maximize the reward value over time.

11. The computer system of claim 10 wherein the action comprises a set of values that correspond to input stimuli to be provided as input to the IC design.

12. The computer system of claim 10 wherein the input stimuli pertain to a particular interface of the IC design that is associated with the RL agent, and wherein each RL agent in the plurality of RL agents is associated with a different interface of the IC design.

13. The computer system of claim 10 wherein the reward value indicates whether application of the action to the testbench environment resulted in an improvement in one or more coverage metrics for the IC design.

14. The computer system of claim 10 wherein the reward value is a positive value in a scenario where application of the action to the testbench environment resulted in an improvement in one or more coverage metrics for the IC design.

15. The computer system of claim 10 wherein the reward value is a zero or negative value in a scenario where application of the action to the testbench environment resulted in no improvement in one or more coverage metrics for the IC design.

16. The computer system of claim 10 wherein the instructions further cause the processor to:
set the new state as the current state; and
repeat the determining and transmitting of the action, the receiving of the reward value and the new state, and the training of the RL model, policy, or function until all coverage goals for the IC design are met.

17. The computer system of claim 10 wherein the current state includes a concatenated sequence of one or more prior actions determined by the RL agent.

18. The computer system of claim 10 wherein the RL model, policy, or function of the RL agent was previously trained using a replay buffer, the replay buffer comprising information pertaining to a suite of test cases that was previously executed against the testbench environment.

19. A non-transitory computer-readable medium having stored thereon instructions executable by a reinforcement learning (RL) agent in a plurality or RL agents, the instructions causing the RL agent to:
receive a current state of a testbench environment for an integrated circuit (IC) design;
determine, via an RL model, policy, or function, an action to be applied to the testbench environment based on the current state;
transmit the action to the testbench environment;
receive from the testbench environment a reward value and a new state of the testbench environment that is responsive to the action; and
train the RL model, policy, or function based on the reward value, the current state, and the action, the training causing the RL model, policy, or function to learn mappings between states of the testbench environment and actions to be applied to the testbench environment that maximize the reward value over time.

20. The non-transitory computer-readable storage medium of claim 19 wherein the RL agent is associated with an interface of the IC design and wherein the action determined by the RL agent corresponds to input stimuli to be input to the IC design via the interface.
